(19) United States
(12) Patent Application Publication
(10) Pub. No.: US 2006/0132159 A1
(43) Pub. Date: Jun. 22, 2006

(54) Burn-in apparatus

(76) Inventor: Masayuki Tamaishi, Kashihara-shi (JP)

Correspondence Address: MORRISON & FOERSTER LLP, 755 PAGE MILL RD, PALO ALTO, CA, 94304-1018, US

(21) Appl. No.: 11/282,343

(22) Filed: Nov. 18, 2005

(30) Foreign Application Priority Data
Nov. 19, 2004 (JP) P2004-336277

(51) Int. Cl. G01R 31/02

(52) U.S. Cl. 324/760

(57) ABSTRACT

A radiating portion of each semiconductor laser element held by a holding portion contacts a heat sink, and therefore heat generated by operation of the semiconductor laser element is transmitted to the heat sink. A heat pipe is provided along an array direction of the semiconductor laser element held by the holding portion. The heat pipe transmits the heat to the heat sink which transmits the heat to the heat pipe, so that a temperature variation of the heat sink can be reduced along the array direction of the semiconductor laser element. This makes it possible to reduce the temperature variations of the semiconductor laser element.

### BACKGROUND OF THE INVENTION

1. Field of the Invention

The present invention relates to a burn-in apparatus for use in, for instance, burn-in test step and aging test step of test objects such as a semiconductor apparatus.

2. Description of the Related Art

In related arts, a housing space of one thermostatic bath densely contains a plurality of semiconductor laser elements, and a temperature of the housing space is maintained to be a predetermined degree. In this case, the semiconductor laser element is driven so that semiconductor laser element which causes operational failure is detected (refer to, for instance, Japanese Unexamined Utility Model Publication JP-U 07-002933 (1995)).

In related arts, temperatures of a plurality of the semiconductor laser elements contained in the housing space are not equalized. This causes a problem that testing condition for each semiconductor laser element is different from each other. Accordingly, for practical purposes, a metallic heat sink is provided so as to contact a plurality of semiconductor laser elements in order to equalize the temperatures of a plurality of semiconductor laser elements. However, even when the heat sink is provided, there is left a problem that variation occurs in temperature of a plurality of the semiconductor laser elements since heat of the semiconductor laser element is not sufficiently transmitted to each other. In particular, a semiconductor laser element which causes operational failure has a lower temperature than a semiconductor laser element which normally operates. Consequently, in a case where such a semiconductor laser element causing operational failure is included, there is a problem that the semiconductor laser elements contacting the same heat sink have larger temperature variation.

### SUMMARY OF THE INVENTION

An object of the invention is to provide a burn-in apparatus capable of preparing uniform testing conditions by reducing temperature variation of a plurality of test objects which generates heat in operation thereof and enhancing reliability of burn-in test and aging test.

The invention provides a burn-in apparatus comprising:

a thermostatic bath having a housing space capable of housing a plurality of test objects having a heat generating portion which generates heat in operation thereof;

a holding portion provided in the housing space, for holding a plurality of test objects;

operational state detecting portion for giving test objects held by the holding portion an operational signal for operating the test objects, detecting outputs of the test objects to which the operation signal is given, and then outputting a detected result as a operational state;

a heat sink provided in the housing space, for contacting the heat generating portions of the test objects held by the holding portion; and

a heat pipe provided on the heat sink along an array direction of the test objects held by the holding portion, for transmitting heat of the heat sink.

According to the invention, operational signals are given to a plurality of test objects contained in a housing space of a thermostatic bath by an operational state detecting portion and then, a normal test object operates among the test objects. The operational state detecting portion detects outputs of the test objects to which the operational signal is given, and outputs a detected result, that is to say, an operational state indicating whether the test objects normally operates or causes operational failure. Accordingly, by obtaining the outputs, it is possible to conduct so-called burn-in test and aging test for determining a test object which causes initial failure and a test object which may cause an operational failure due to use for a long period of time.

Since heat generating portions of the test objects held by the holding portion contact a heat sink, heat generated by operation of the test objects is transmitted to the heat sink. A heat pipe is provided on the heat sink along an array direction of the test objects held by the holding portion. The heat pipe transmits the heat to the heat sink which transmits the heat to the heat pipe, so that a temperature variation of the heat sink can be reduced along the array direction of the test objects. This makes it possible to reduce the temperature variations of the test objects.

In particular, in a case where a plurality of the test objects include a test object causing operational failure, this test object has a lower temperature than that of a test object which normally operates while the heat sink contacting the test object causing operational failure has a lower temperature than that of the heat sink abutting on the test object which normally operates. This decreases temperatures of the test objects around the test object which causes the operational failure. However, the heat of the heat sink is transferred by the heat pipe having higher heat conductivity than that of the heat sink. By so doing, the temperature variations of the test objects can be as well reduced as possible so that temperatures of the test objects can be made as uniform as possible.

Thus, by equalizing the temperatures of the test objects, the testing conditions of the test objects can be equalized so that the reliability of the burn-in test and aging test can be enhanced.

Further, in the invention, it is preferable that a plurality of the holding portions are provided so as to be away from each other, and a plurality of the heat sinks are provided so as to correspond to the holding portions, the heat sinks being connected to each other via the heat pipe.

Further, according to the invention, a plurality of the holding portions are provided. The holding portion is provided so as to be away from each other, for instance with air interposed therebetween so that the heat is hardly transmitted to each other. A plurality of the heat sinks are provided so as to correspond to the holding portions. Accordingly, the heat sinks are away from each other.

Since the heat sinks are connected to each other via the heat pipe, the heat of the heat sinks is transmitted to the other heat sink via the heat pipe. Thereby, even when the holding portions hold the different number of operating test objects, it is possible to reduce variation in temperature between the heat sink on the holding portion holding the large number of the operating test objects, and the heat sink on the holding portion holding the small number of the operating test objects so that the temperature variations of the test objects held by the holding portions can be as well reduced as possible.

Further, in the invention, it is preferable that the heat pipe is connected to the heat sink via a paste-like filling material composed of metal powder and grease.

Further, according to the invention, the heat pipe is connected to the heat sink via a paste-like filling material composed of metal powder and grease. When gas is interposed between the heat pipe and the heat sink, the gas becomes a large heat transfer resistance so that the heat is prevented from being transferred between the heat pipe and the heat sink. However, by interposing the paste-like filling material composed of metal powder and grease between the heat pipe and the heat sink, the heat is smoothly transmitted between the heat sink and the heat pipe. The temperature variation of the semiconductor laser elements can be further reduced. The metal powder is, for instance, formed of copper.

Further, in the invention, it is preferable that the holding portion has a press portion for elastically pushing onto the heat sink a radiating portion of the test object, for radiating the heat generated by the heat generating portion.

Further, according to the invention, a radiating portion of the test object is elastically pushed onto the heat sink by a press portion and therefore, it is possible to reliably contact the radiating portion with the heat sink while preventing a load given to the test object from being too large.

Further, in the invention, it is preferable that the burn-in apparatus further comprises:

a temperature detecting portion for detecting a temperature of the heat pipe; and

a temperature maintaining portion for maintaining, based on a detected result of the temperature detecting portion, a temperature of atmosphere in the housing space so that a plurality of the test objects held by the holding portion have temperatures within a predetermined temperature range.

Further, according to the invention, a temperature of the heat pipe is detected by the temperature detecting portion, and based on this detected result, the temperature maintaining portion adjusts atmosphere in the housing space so that a plurality of the test objects held by the holding portion have temperatures within a predetermined temperature range. The temperature of the heat pipe changes in acute response to changes of the temperatures of the test objects, so that the temperature of the heat pipe becomes a standard for indicating the temperatures of a plurality of the test objects. Since the heat of the test objects is transmitted to the heat pipe via the heat sink, it is possible to measure the temperature of the test object by measuring the temperature of the heat pipe without directly measuring the temperature of the test objects. On the basis of the detected result that the temperature of the heat pipe has been detected, the temperature maintaining portion adjusts the temperature of the atmosphere in the housing space. By so doing, with a simple configuration, it is possible to maintain the temperatures of a plurality of the test objects held by the holding portion to fall within the predetermined temperature range.

### BRIEF DESCRIPTION OF THE DRAWINGS

Other and further objects, features, and advantages of the invention will be more explicit from the following detailed description taken with reference to the drawings wherein:

FIG. 1 is a schematic view showing a configuration of a burn-in apparatus according to one embodiment of the invention;

FIG. 2 is a schematic sectional view showing a configuration of the burn-in apparatus taken on a section line II-II of FIG. 1;

FIG. 3 is a schematic sectional view showing a configuration of the burn-in apparatus in a test state where a housing space is isolated from an external space in FIG. 2;

FIG. 4 is a functional block diagram showing an electrical structure of the burn-in apparatus;

FIG. 5 is an enlarged plan view showing a holding portion, a heat sink, and a heat pipe;

FIG. 6 is an enlarged sectional view showing a section VI of FIG. 3;

FIG. 7 is an enlarged sectional view showing a section VII of FIG. 2;

FIG. 8 is a plan view showing a plurality of semiconductor laser elements in a state of being connected to a frame;

FIG. 9 is an enlarged view showing one of a plurality of the semiconductor laser elements connected to the frame; and

FIG. 10 is a sectional view showing the burn-in apparatus taken on a section line X-X of FIG. 2.

### DETAILED DESCRIPTION

Now referring to the drawings, preferred embodiments of the invention are described below.

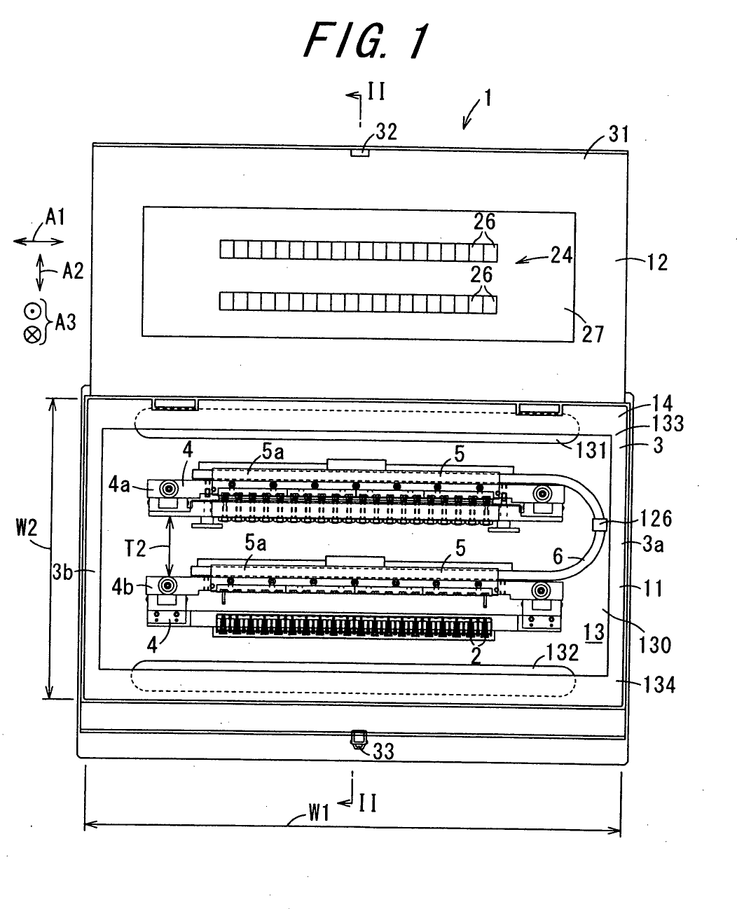

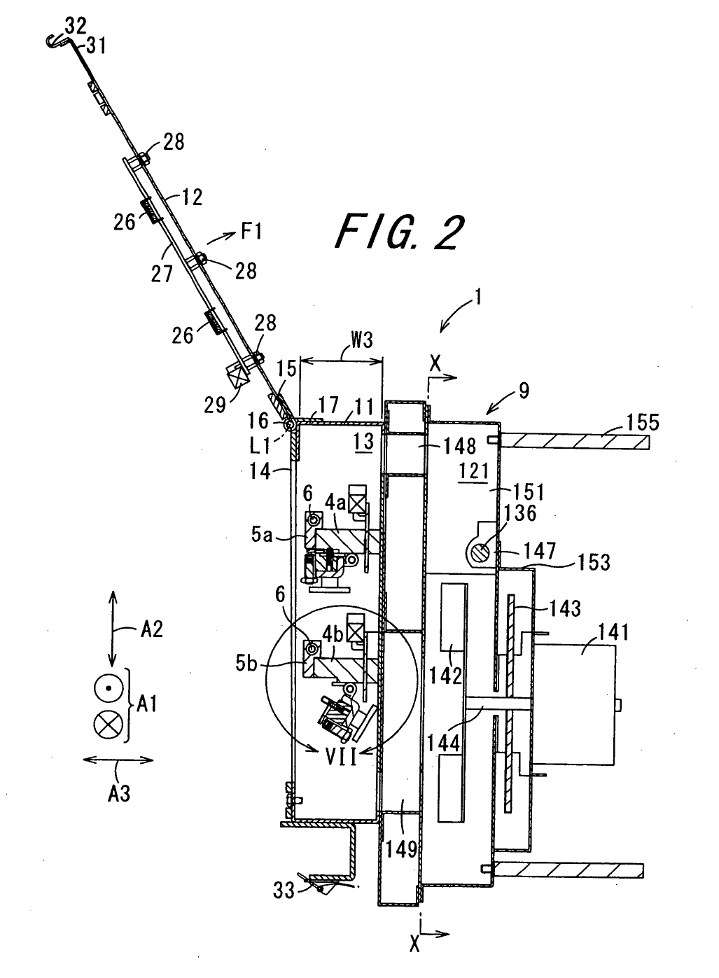

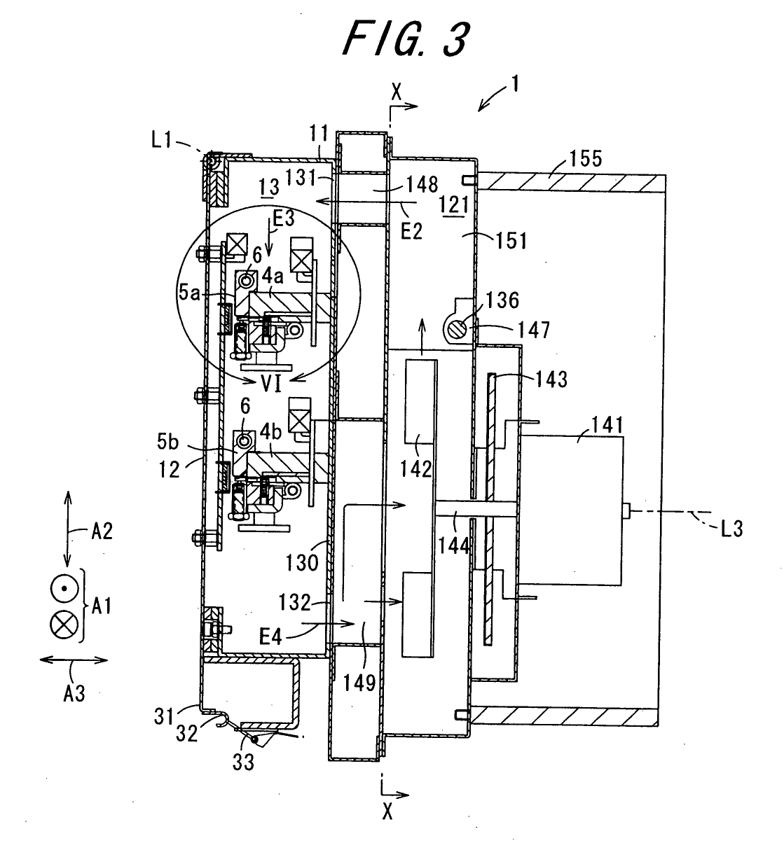

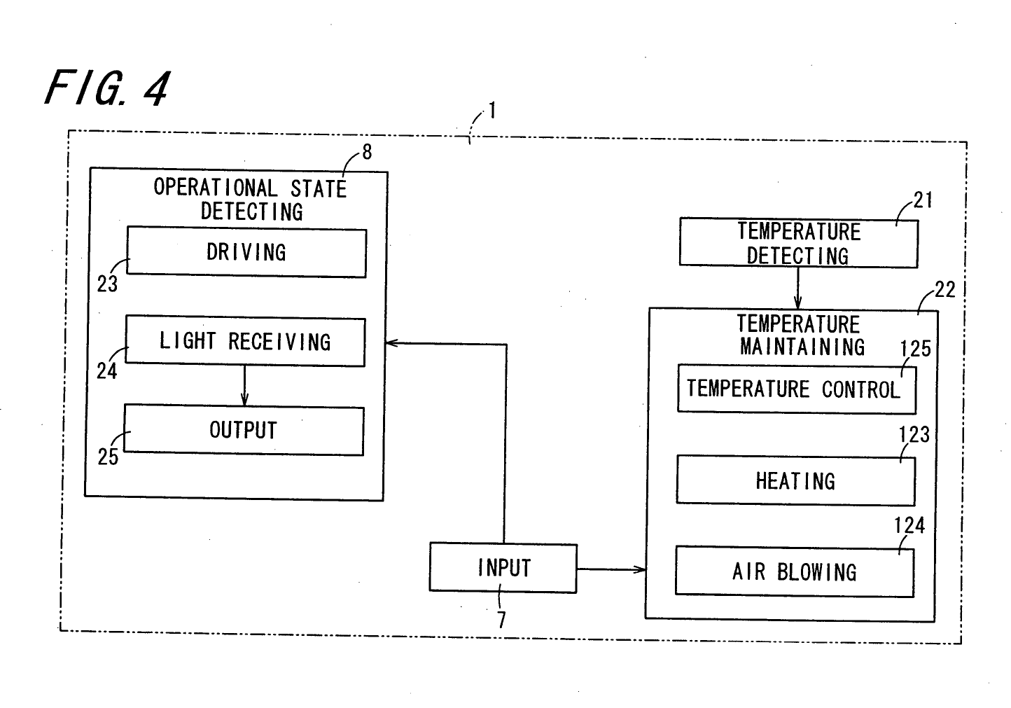

FIG. 1 is a schematic view showing a configuration of a burn-in apparatus 1 according to one embodiment of the invention. FIG. 1 shows the burn-in apparatus 1 in a state where a housing space 13 is exposed to an external space of a thermostatic bath 3. FIG. 2 is a schematic sectional view showing a configuration of the burn-in apparatus 1 taken on a section line II-II of FIG. 1. FIG. 3 is a schematic sectional view showing a configuration of the burn-in apparatus 1 in a test state where the housing space 13 is isolated from an external space in FIG. 2. FIG. 4 is a functional block diagram showing an electrical structure of the burn-in apparatus 1.

The burn-in apparatus 1 is used for burn-in test and aging test of test objects. In the burn-in test, the burn-in apparatus 1 detects the test objects, which may cause initial failure, by operating the test objects for a certain period of time before use. Further, in the aging test, the burn-in apparatus 1 detects states of the test objects when the test objects are operated in an environment having a predetermined temperature that is higher than a room temperature so as to be stressed, and by so doing, detects reliability thereof in a case where the test objects are used for a long period of time. In the present embodiment, the test object is a semiconductor laser element 2. The semiconductor laser element 2 comprises a heat generating portion which generates heat. In FIGS. 1 to 3, the semiconductor laser elements 2 are shown by solid lines.

The burn-in apparatus 1 comprises a thermostatic bath 3, a first holding portion 4a, a second holding portion 4b, a first heat sink 5a, a second heat sink 5b, a heat pipe 6, input portion 7, operational state detecting portion 8, and temperature adjusting portion 9.

The thermostatic bath 3 serves as a housing container, and comprises a thermostatic bath main body 11 and a thermostatic lid 12. The thermostatic bath 3 includes a predetermined housing space 13 in which a plurality of the semiconductor laser elements 2 can be contained. Hereinafter, the predetermined housing space 13 is simply referred to as a housing space 13. The thermostatic main body 11 has an inner peripheral surface formed into a schematic tube with bottoms. An opening 14 of the thermostatic main body 11 is formed to have a schematic rectangle shape. The thermostatic lid 12 is provided on the thermostatic main body 11 so that the housing space 13 can be exposed to the external space of the thermostatic bath 3 and so that the housing space 13 can be isolated from the external space of the thermostatic bath 3. A state where the housing space 13 is exposed to the external space of the thermostatic bath 3 as shown in FIG. 2 is referred to as an open state. A state where the housing space 13 is isolated from the external space of the thermostatic bath 3 as shown in FIG. 3 is referred to as a closed state. The thermostatic bath 3 is formed of metal materials such as stainless steel and iron.

The thermostatic lid 12 has a shape of rectangle plate, a surface of which, facing the housing space 13 in the closed state, is formed into a flat surface. The thermostatic bath lid 12 has an end 15 thereof coupled to an end 17 of the opening 14 of the thermostatic bath main body 11 by a first hinge portion 16. The thermostatic bath lid 12 can be angularly displaced about an axis line L1 of the first hinge portion 16. In the closed state, the thermostatic bath lid 12 abuts on the opening 14 so that the opening of the thermostatic bath main body 11 is closed. When the thermostatic bath lid 12 is angularly displaced in an arrow F1 direction shown in FIG. 2 about the axis line L1 from the closed state, the inner peripheral surface of the thermostatic bath main body 11 is exposed. The housing space 13 of the thermostatic bath 3 is a region surrounded by the inner peripheral surface of the thermostatic bath 3. The housing space 13 in the closed state has a schematic rectangular parallelepiped shape.

In the closed state, a dimension in a direction facing the housing space 13, of the thermostatic bath 3 in a first direction A1 (a right-and-left direction in FIG. 1) in parallel with a direction in which the axis line L1 extends, is referred to as W1. A dimension in the direction facing the housing space 13, of the thermostatic bath 3 along a second direction A2 (a up-and-down direction in FIG. 1) which is vertical to the first direction A1 and which is parallel to the surface of the thermostatic bath lid 12 in the closed state, the surface facing the housing space 13, is referred to as W2. A dimension in the direction facing the housing space 13, of the thermostatic bath 3 along a third direction A3 (a vertical direction to FIG. 1 sheet) which is vertical to the first direction A1 and the second direction A2, is referred to as W3. In this case, for instance, the W1 is selected to be within a range of from a range of 200 mm to 500 mm, W2 from a range of 100 mm to 300, and W3 from a range of 25 mm to 80 mm. In the embodiment are selected, for instance, W1=350 mm, W2=170 mm, and W3=50 mm.

The first holding portion 4a and the second holding portion 4b are contained in the housing space 13 formed in the thermostatic bath 3. The first holding portion 4a and the second holding portion 4b can detachably hold a plurality of the semiconductor laser elements 2. The first heat sink 5a and the second heat sink 5b are provided in the housing space. The first heat sink 5a contacts an after-described radiating portion of the semiconductor laser element 2 held by the first holding portion 4a. The second heat sink 5b contacts a radiating portion of the semiconductor laser element 2 held by the second holding portion 4b. The heat pipe 6 is provided on the first heat sink 5a and the second heat sink 5b along an array direction of the semiconductor laser elements 2 held by the first holding portion 4a and the second holding portion 4b so as to transmit heat of the first heat sink 5a and the second heat sink 5b. The holding portion 4, the first heat sink 5a, the second heat sink 5b, and the heat pipe 6 will be described hereinbelow.

The input portion 7 is an interface for inputting command information indicating an operational command given to the burn-in apparatus 1. The inputted command information is given to the operational state detecting portion 8 and temperature maintaining portion 22 which will be described hereinbelow. This makes it possible to operate the burn-in apparatus 1 to conduct the testing. To the input portion 7, for instance, is detachably connected an information-processing unit which is implemented by a computer and from which the command information is given. The command information includes initializing information which indicates a start command for initializing the testing by the burn-in apparatus 1, ending information which indicates an end command for ending the testing by the burn-in apparatus 1, and driving condition information indicating a condition for driving the semiconductor laser element 2.

The temperature adjusting portion 9 comprises temperature detecting portion 21 and temperature maintaining portion 22. The temperature detecting portion 21 comprises a thermocouple, and detects a temperature of the heat pipe 6 which will be described hereinbelow. The temperature maintaining portion 22 adjusts a temperature of atmosphere in the housing space 13 of the thermostatic bath 3 on the basis of the detected result of the temperature detecting portion 21 so that the temperature of the semiconductor laser element 2 held by the holding portion 4 is maintained within a predetermined temperature range. The temperature maintaining portion 22 operates when the initializing information is given from the input portion 7. Moreover, the temperature maintaining portion 22 stops operation thereof when the ending information is given from the input portion 7.

The operational state detecting portion 8 gives an operational signal for operating the semiconductor laser element 2 held by the holding portion 4 on the basis of the driving condition information given by the input portion 7, and detects an output of the semiconductor laser element 2 to which the operation signal is given, so as to output the detected result as an operational state. The operational state detecting portion 8 comprises a driving portion 23 for giving a driving signal to the semiconductor laser element 2, a light-receiving portion 24 for detecting the output of the semiconductor laser element 2 by receiving a light emitted by the semiconductor laser element 2, and an output portion 25 for outputting a predetermined signal indicating the operational state of the semiconductor laser element 2.

In the embodiment, the aging test of the semiconductor laser element 2 is conducted by evaluating a change of driving current of the semiconductor laser element 2 when the semiconductor laser element 2 is driven so that a light intensity thereof is constant, in the environment having the predetermined temperature. Such a testing is called as an APC (Automatic power control) test. The predetermined temperature is higher than an air temperature around the thermostatic bath 3, which air temperature is a room temperature. For instance, the predetermined temperature is selected to be within a range of from a range of 50° C. or higher and lower than 80° C. By setting the environment to have such a high temperature than the room temperature, deterioration of the semiconductor laser element 2 can be accelerated so that estimation can be made about a property of the aging change on the semiconductor laser element 2 when used for a long period of time.

The light receiving portion 24 is correspondingly provided on the semiconductor laser element 2 held by the holding portion 4. The light receiving portion 24 receives a light outputted by each of the driven semiconductor laser elements 2. The light receiving portion 24 comprises a plurality of light receiving elements 26 for outputting electronic signals in accordance with light intensity. The light receiving element 26 is composed of, for instance, photodiodes such as indium gallium arsenide (InGaAs) photodiode. With the InGaAs photodiode, a dark current is changed within a small range even when the temperature of atmosphere having the InGaAs photodiode disposed therein changes. Accordingly, the light intensity of the semiconductor laser element 2 can be reliably detected even when the InGaAs photodiode is contained in the thermostatic bath 3 having the semiconductor laser element 2 contained therein. An after-described mounting portion 27 is provided with a light receiving portion connector 29. The light receiving element 26 is connected to the light receiving portion connector 29 via wires provided on the mounting portion 27. To the light receiving portion connector 29 is detachably connected a harness. To the light receiving element 26 is connected the driving portion 23 and the output portion 25 via the light receiving portion connector 29 and the harness.

The driving portion 23 gives a driving current to the semiconductor laser element 2 held by the holding portion 4. TO be specific, the driving portion 23 adjusts the driving current given to the semiconductor laser element 2 on the basis of the light intensity of the semiconductor laser element 2, which light intensity has been detected by the light receiving element 26, so that the light intensity is constant. And then, the driving portion 23 gives the driving current to the semiconductor laser element 2. Moreover, the driving portion 23 gives a signal to the output portion 25, which signal indicates the driving current of the semiconductor laser element 2. In the embodiment, the information indicating the operational state of the semiconductor laser element 2 signifies the signal indicating the driving current of the semiconductor laser element 2 in the APC test.

The output portion 25 comprises a connector. The output portion 25 comprises a driving current output terminal for outputting the signal indicating the driving current of the semiconductor laser element 2. In the semiconductor laser element 2 which causes operational failure, a threshold of the driving current becomes larger than the predetermined threshold. This makes it possible to determine whether the semiconductor laser element 2 causes the operational failure.

The thermostatic bath lid 12 has the mounting portion 27 for detachably mounting a plurality of the light receiving elements 26 on the receiving portion 24. A plurality of the light receiving elements 26 on the receiving portion 24 are detachably mounted on the thermostatic bath lid 12 by the mounting portion 27. The mounting portion 27 is detachably fixed to the thermostatic bath lid 12 by a screw member 28 in a state where the mounting portion 27 is slightly away from the thermostatic bath lid 12. The light receiving element 26 on the light receiving portion 24 faces the semiconductor laser element 2 held by the holding portion 4 in the closed state.

On a free end 31 of the thermostatic bath lid 12 is formed an engaging portion 32. On the thermostatic bath main body 11 is provided a locking portion 33 for locking the thermostatic bath lid 12 in the closed state by engaging the engaging portion 32 with the locking portion 33. Due to the locking that the engaging portion 32 is engaged with the locking portion 33, the thermostatic bath main body 11 and the thermostatic bath lid 12 are firmly attached to each other so that airtightness in the housing space 13 can be enhanced and in addition, it is possible to prevent the housing space 13 from being exposed to the external space of the thermostatic bath 3 during the testing on the semiconductor laser element 2. In the housing space 13 exists a predetermined gas. In the embodiment, the predetermined gas is air.

The first holding portion 4a and the second holding portion 4b hold a plurality of the semiconductor laser elements 2 in array from a region close to one end 3a to a region close to the other end 3b in the first direction A1 of the thermostatic bath main body 11. Two holding portion are provided so that the first holding portion 4a and the second holding portion 4b have a predetermined distance T2 in the second direction A2 therebetween. The predetermined distance T2 is selected so that heat of the first holding portion 4a and heat of the second holding portion 4b are hardly transmitted to each other by interposing air therebetween. For instance, the predetermined distance T2 is selected to be within a range of from 5 cm to 20 cm. Hereinbelow, the first holding portion 4a and the second holding portion 4b may be collectively referred to as the holding portion 4 in a simple manner. The first holding portion 4a and the second holding portion 4b have the same configuration.

Each of the holding portions 4 holds a plurality of the semiconductor laser elements 2 arranged in a row along the first direction A1. Each of the holding portions 4 can hold 20 semiconductor laser elements 2. The holding portion 4 holds the semiconductor laser element 2 so that an emitting end face of the semiconductor laser element 2 faces the light receiving element 26 on the light receiving portion 24 provided on the thermostatic bath lid 12. The holding portions 4 are provided in parallel with each other. In the closed state, the light receiving portion 24 of each of the light receiving elements 26 and the semiconductor laser element 2 corresponding to this light receiving portion 24 face each other with a slight distance T1 therebetween. The distance T1 is selected to be within a range of from 0.2 mm to 3.0 mm, for instance.

In another embodiment of the invention, the number of the semiconductor laser elements 2 held by the holding portion 4 is not limited to 20, but the holding portion 4 may be capable of holding around 10 to 100 semiconductor laser elements 2, for instance.

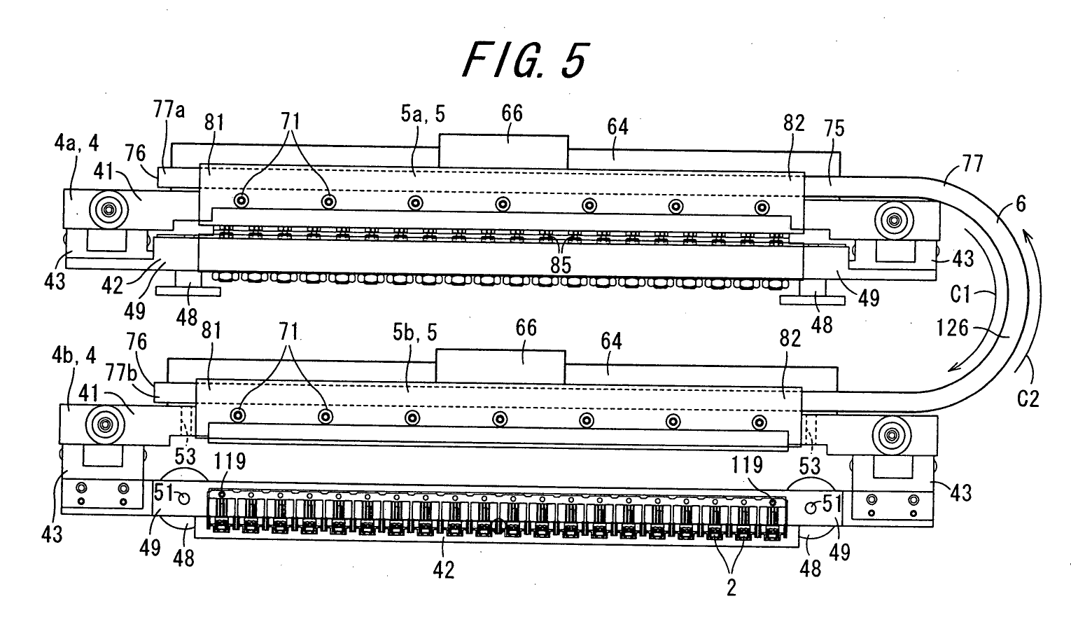

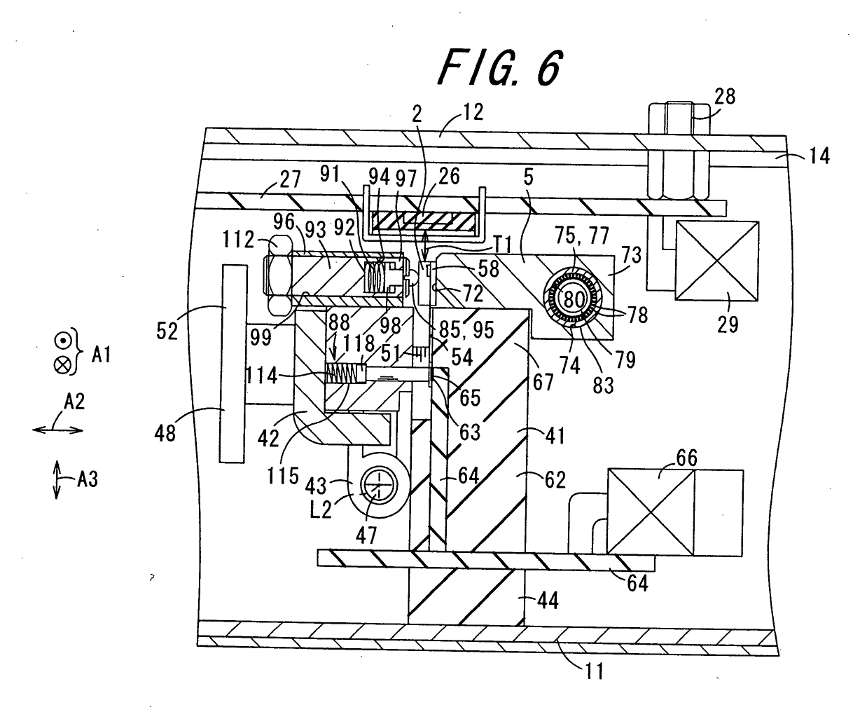

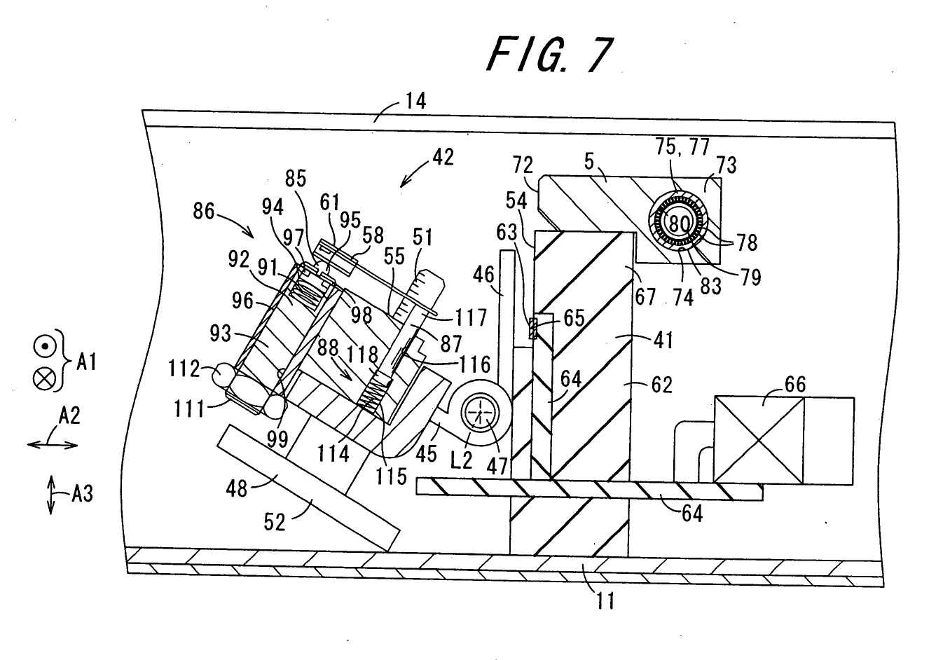

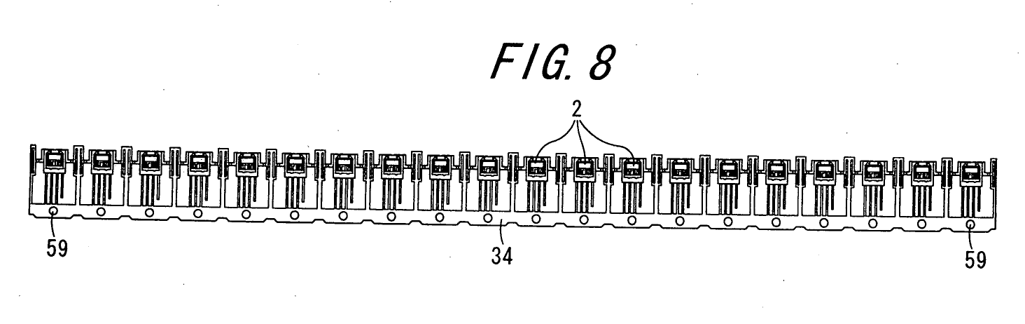

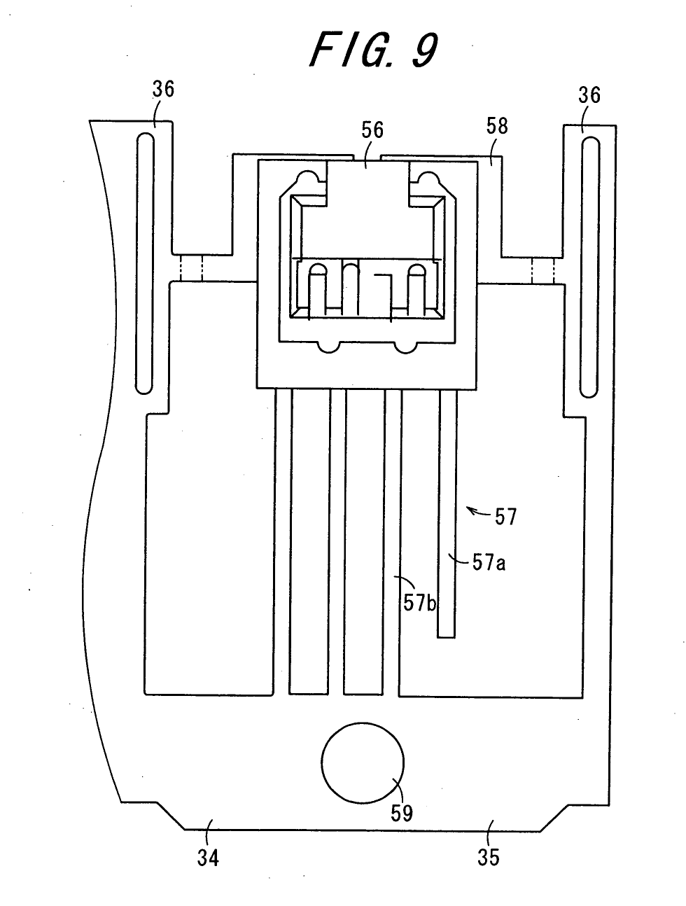

FIG. 5 is an enlarged plan view showing the holding portion 4, a heat sink 5, and the heat pipe. FIG. 6 is an enlarged sectional view showing a section VI of FIG. 3. FIG. 7 is an enlarged sectional view showing a section VII of FIG. 2. FIG. 8 is a plan view showing a plurality of the semiconductor laser elements 2 in a state of being connected to a frame 34. FIG. 9 is an enlarged view showing one semiconductor laser element 2 of a plurality of the semiconductor laser elements 2 connected to the frame 34. In FIGS. 5 to 7, the semiconductor laser elements 2 are shown by solid lines.

The holding portion 4 has a base portion 41 fixed to the thermostatic bath main body 11, and a movable portion 42 provided on the base portion 41 so as to be capable of being angularly displaced. The movable portion 42 is coupled to the base portion 41 on a proximal portion 44 side of the base portion 41. A second hinge portion 43 comprises a first coupling piece 45, a second coupling piece 46, and an axial portion 47 by which the first coupling piece 45 and the second coupling piece 46 are coupled to each other so as to be capable of being angularly displaced. The first coupling piece 45 and the second coupling piece 46 can be relatively displaced about an axis line L2 of the axial portion 47. The first coupling piece 45 is connected to the movable portion 42. The second coupling piece 46 is fixed to the base portion 41. Therefore, the movable portion 42 can be angularly displaced about the axis line L2. The axis line L2 extends in parallel with the first direction A1.

The holding portion 4 holds a plurality of the semiconductor laser elements 2 by having a plurality of the semiconductor laser elements 2 sandwiched between the base portion 41 and the movable portion 42. When a plurality of the semiconductor laser elements 2 are sandwiched between the movable portion 42 and the base portion 41, the movable portion 42 is provided with a displacement holdback portion 48 for preventing the movable portion 42 and the base portion 41 from being relatively displaced. The displacement holdback portion 48 is provided on each of both ends 49 in a longitudinal direction, that is to say, the first direction A1 of the movable portion 42. The displacement holdback portion 48 comprises a male screw forming portion 51 on which a male screw is formed, and a pinch portion 52 for rotating the male screw forming portion 51 about an axis line of the male screw forming portion 51. The pinch portion 52 is supported by the movable portion 42 so as to be rotatable about the axis line of the male screw forming portion 51. On the movable portion 42 is formed a female screw portion 53 corresponding to the male screw forming portion 51. Between the movable portion 42 and the base portion 41 is sandwiched a plurality of the semiconductor laser elements 2, and the pinch portion 52 is manipulated so that the male screw forming portion 51 is screwed into the female screw portion 53. By so doing, the movable portion 42 and the base portion 41 are prevented from being relatively displaced.

A state where the movable portion 42 and the base portion 41 are relatively displaced angularly so that the semiconductor laser element 2 can be held between the movable portion 42 and the base portion 41, is referred to as a held state. A state where the semiconductor laser element 2 held between the movable portion 42 and the base portion 41 can be detached, is referred to as a developed state. The base portion 41 has a first holding surface 54 facing the movable portion 42 in the held state. The movable portion 42 has a second holding surface 55 facing the base portion 41 in the held state. In the held state, the semiconductor laser element 2 is held between the first holding surface 54 and the second holding surface 55. The first holding surface 54 and the second holding surface 55 are flat surfaces. The first holding surface 54 is vertical to the second direction A2.

A plurality of the semiconductor laser elements 2 are held by the holding portion 4 in a state of being connected to the frame 34. The frame 34 is formed of conductive materials such as aluminum. A plurality of the semiconductor laser elements 2 are held by the holding portion 4 in a state of being connected to the frame 34. By so doing, compared to a case where the semiconductor laser element 2 is held by the holding portion 4 one by one, a plurality of the semiconductor laser element 2 can be easily held by the holding portion 4 and detached from the holding portion 4 so that a length of time for exchanging the tested semiconductor laser elements 2 can be reduced, and a test efficiency can be enhanced.

The frame 34 is coupled to a plurality of the semiconductor laser elements 2 so that the emitting end faces of a plurality of the semiconductor laser elements 2 face in the same direction. The frame 34 comprises a frame base portion 35 which is connected to a free end of an element terminal portion 57 of the semiconductor laser element 2 and which extends along the array direction of the semiconductor laser elements 2, and a frame projecting portion 36 which protrudes from the frame base portion 35 to a side having the semiconductor laser element 2 connected thereto and which extends to a side of an element main body 56 of the semiconductor laser element 2. The frame projecting portion 36 is mutually connected to a radiating portion 58 of the semiconductor laser element 2.

The semiconductor laser element 2 has the element main body 56 and an element terminal portion 57. The element main body 56 comprises a semiconductor laser chip and the radiating portion 58. The semiconductor laser chip is a heat generating portion. The radiating portion 58 has a function of radiating heat generated on the semiconductor laser chip. The element terminal portion 57 has a plus (+) terminal 57a and a ground terminal 57b which protrude from the element main body 56, for supplying current for driving the semiconductor laser element 2. The semiconductor laser element 2 contains a semiconductor laser chip for use in CDs (compact disk) or DVDs (digital versatile disk), for instance. The semiconductor laser chip may be configured to output light of single wavelength or two wavelengths.

The ground terminal 57b is coupled to the radiating portion 58 and the frame 34. On the frame 34 is formed a positioning hole 59. By fitting this positioning hole 59 in a projecting portion 119 of the holding portion 4 which will be described hereinbelow, the semiconductor laser element 2 can be positioned on the holding portion 4. The radiating portion 58 has a radiating surface 61 which is formed into a flat surface. Each terminal of the element terminal portion 57 is formed closer to a center of the element main body 56 than the radiating surface 61, and extends in parallel with the radiating surface 61.

The base portion 41 comprises a base portion main body 62 formed of heat insulating materials such as synthetic resin, a connecting terminal portion 63 with which the element terminal portion 57 of the semiconductor laser element 2 makes contact in the held state, a base substrate 64 on which wires formed of conducting materials are formed, and a connector portion 66. The connecting terminal portion 63 has a terminal piece 65 individually contacting the plus terminal 57a and ground terminal 57b of a plurality of the semiconductor laser elements 2 which can be held by the holding portion 4. The terminal piece 65 is formed of a conductive material. The terminal piece 65 is provided so as to slightly protrude from the first holding surface 54 of the base portion 41. The terminal piece 65 is connected to the connector portion 66 via the wires formed on the base substrate 64. To the connector portion 66 is detachably connected a harness. The harness is connected to the driving portion 23. The driving current is given to the semiconductor laser element 2 via the harness, the connector portion 66, the wires formed on the substrate, and the terminal piece 65.

The first heat sink 5a is provided on the first holding portion 4, and the second heat sink 5b is provided on the second holding portion 4. The first heat sink 5a and the second heat sink 5b have the same configuration. The first heat sink 5a and the second heat sink 5b may be collectively referred to as the heat sink 5 in a simple manner.

The heat sink 5 is provided on the free end of the base portion 41, that is to say, the other end 67 in the third direction A3. The heat sink 5 is detachably fixed to the base portion main body 62 by a metallic second screw member 71. The heat sink 5 is formed of aluminum. The heat sink 5 has a contact surface 72 with which the radiating portion 58 of the semiconductor laser element 2 held by the holding portion 4 makes contact in the held state. The contact surface 72 is flat and vertical to the second direction. The heat sink 5 is provided so that the contact surface 72 is slightly away to one side in the second direction to the first holding surface 54. The element terminal portion 57 of the semiconductor laser element 2 is provided closer to the center of the element main body 56 than the radiating surface 61 of the radiating portion 58. An amount of the contact surface 72 of the heat sink 5, which is away from the first holding surface 54 to one side in the second direction, is selected so that the terminal piece 65 contacts the first holding surface 54 in a state where the radiating portion 58 of the semiconductor laser element 2 contacts the contact surface 72. The heat sink 5 is formed so that a surface area thereof is as large as possible and so that a heat capacity thereof is as small as possible.

The heat sink 5 is provided with the heat pipe 6. The heat sink 5 has a heat pipe holding portion 73 for holding the heat pipe 6. The heat pipe holding portion 73 has a through hole 74 of which inside diameter is slightly larger than a diameter of the heat pipe 6. The through hole 74 extends along the longitudinal direction of the heat sink 5, that is to say, in the array direction of the semiconductor laser elements 2 held by the heat pipe holding portion 73.

The heat pipe 6 comprises a case body 77 having a tubular-shaped cylinder portion 75 and a closing portion 76 for closing openings on both ends of the cylinder portion 75, a wick material 78 provided in a space surrounded by the case body 77 between both end 77a and end 77b of the case body 77, and a heat medium. The heat pipe 6 is a so-called wick-type heat pipe. The heat pipe 6 has heat conductivity which is several times to several dozens of times as high as that of the heat sink 5. The wick material 78 extends between the both end 77a and end 77b of the case body 77. The wick material 78 includes a plurality of metal wire materials made of metal. There are provided several dozens to several hundreds of metal wire materials. The wick material 78 is pushed by a heat pipe screw member 79 toward an inner peripheral surface 80 of the case body 77. By so doing, a predetermined space is formed in a center portion of an inside space of the case body 77. The inside space of the case body 77 has a decreased pressure. A small amount of the heat medium is included in the inside space of the case body 77. When a temperature difference is generated in a direction that the heat pipe 6 extends, in the inside space of the case body 77, the heat medium in liquid form evaporates at a high-temperature portion while absorbing evaporation latent heat from the case body 77, and the evaporated heat medium is condensed at a low-temperature portion by releasing the evaporation latent heat to its surroundings. The condensed heat medium, that is to say, the liquid heat medium refluxes to the high-temperature portion-side in the wick material 78 by capillary phenomenon. By so doing, the evaporation latent heat is transferred from the high-temperature portion to the low-temperature portion, in other words, the heat is transferred in the direction that the heat pipe 6 extends, by means of phase change of the heat medium. By the heat transfer from the high-temperature portion to the low-temperature portion, the temperature on the high-temperature portion decreases while the temperature on the low-temperature portion increases, and thermal equilibrium state will be achieved afterward so that temperature variation can be reduced. A diameter of the heat pipe 6 is selected to be within a range of from 4 mm to 6 mm, for instance. The case body 77 is made of a steel material. In the other embodiments of the invention, the case body 77 may be formed of aluminum and stainless steel. Further, the heat medium is water. In the other embodiments of the invention, the heat medium may be naphthalene, dawtherm-A, methanol, ammonium, acetone, chlorofluorocarbon-12, or the like.

The heat pipe 6 is inserted into the through hole 74 of the heat sink 5, and held by the heat sink 5. Accordingly, the heat pipe 6 extends in parallel with the contact surface 72. A portion of the heat pipe 6, which is held by the heat sink 5, extends in parallel with the array direction of the semiconductor laser elements 2 held by the holding portion 4. The heat pipe 6 is thermally connected to the heat sink 5. The heat pipe 6 transmits the heat of the heat sink 5. The first holding portion 4a and the second holding portion 4b are provided in a state of being away from each other with air interposed therebetween so that the heat is hardly transmitted to each other. Accordingly, the first heat sink 5a and the second heat sink 5b are away from each other, but the heat sinks 5 are connected to each other via the heat pipe 6. Consequently, the heat of the heat sink 5 is transmitted to the other heat sink 5 via the heat pipe 6. Even in a case where the holding portion 4 has the different number of the semiconductor laser elements 2, it is possible to reduce variation in temperature between the heat sink 5 on the holding portion 4 holding the large number of the operating semiconductor laser elements 2, and the heat sink 5 on the holding portion 4 holding the small number of the operating semiconductor laser elements 2, so that temperature variation of the semiconductor laser elements 2 held by the holding portion 4 can be as well reduced as possible.

The heat pipe 6 protrudes from the end 81 and end 82 in the first direction A1 of the heat sink 5, respectively. A portion of the heat sink 6 which protrudes from the other end 82 in the first direction A1 of the heat sink 5 continues and forms a circular arc. Accordingly, the heat pipe 6 is connected to the heat sink 5 in a state of being bent in a substantially U-form.

A paste-like filling material composed of metal powder and grease is interposed between the heat pipe 6 and the heat sink 5, to be specific, between an outer peripheral surface of the case body 77 of the heat pipe 6 and an inner peripheral surface of the heat sink 5 which inner peripheral surface faces the through hole 74. The filling material is realized by a metal paste composed of silicone grease and metal powder. The metal component is preferably copper. When air is interposed between the heat pipe 6 and the heat sink 5, the air becomes a large heat transfer resistance so that the heat is prevented from being transferred between the heat pipe 6 and the heat sink 5. However, by interposing the silicone grease 83 containing the metal powder between the heat pipe 6 and the heat sink 5, the heat is smoothly transmitted between the heat sink 5 and the heat pipe 6 so that the temperature variation of the semiconductor laser element 2 can be further reduced.

The movable portion 42 is provided with a first press portion 85, a first elastic bias portion 86, a second press portion 87, and a second elastic bias portion 88.

The first press portion 85 is elastically biased by the first elastic bias portion 86. The first elastic bias portion 86 comprises a first spring member 91, and a first spring support 92 for supporting the first spring member 91. The first spring member 91, the first spring support 92, and the first press portion 85 are provided on a press screw member 93. The first spring member 91 is composed of a coil spring. The press screw member 93 has a schematic cylindrical shape with a screw formed on an outer peripheral portion thereof. The press screw member 93 has a first hole portion 94 having a shape of a tube with a bottom, which opens to one side of the axial direction. By means of this first hole portion 94, the first spring support 92 is formed. In the first hole portion 94 is contained the first spring member 91 and a part of the first press portion 85. One end in the axial direction of the first spring member 91 contacts a bottom wall of the first hole portion 94, and the other end in the axial direction of the first spring member 91 contacts the first press portion 85 so that the first press portion 85 is biased by spring force to one side in the axial direction. The press screw member 93 is provided on a free end 96 of the movable portion 42.

A tip 95 of the first press portion 85 protrudes from an opening of the press screw member 93 to the outside of the press screw member 93. The tip 95 of the first press portion 85 is formed into a semispherical shape. An inside diameter of one end 97 in the axial direction of the first hole portion 94 of the press screw member 93 is formed to be smaller than an inside diameter of the other parts of the first hole portion 94 of the press screw member 93. A proximal portion 98 of the first press portion 85 is formed into a right cylindrical shape having a larger diameter than the inside diameter of the one end 97 in the axial direction of the first hole portion 94. Therefore, in the developed state, the proximal portion 98 of the first press portion 85 abuts on the one end 97 in the axial direction of the first hole portion 94 by spring force of the first spring member 91, so that the first press portion 85 is prevented from being detached from the movable portion 42. The first press portion 85 is formed of electrical isolating materials such as synthetic resin material.

The press screw member 93 is screwed into a screw hole 99 formed on the movable portion 42. By screwing the press screw member 93 inward and outward about the axis line of the press screw member 93, a distance between the first press portion 85 and the heat sink 5 in the held state can be adjusted. This makes it possible to adjust the press force for pushing the semiconductor laser element 2 sandwiched between the first press portion 85 and the heat sink 5.

On an end 111 of the press screw member 93, which end 111 is opposite to the end from which the first press portion 85 protrudes, there is formed an engaging portion for engaging a engaging tool for rotating the press screw member 93 about the axis line. A nut 112 is screwed into the press screw member 93 so as to cover the engaging portion. By screwing the nut 112 outward so as to be detached from the press screw member 93, the engaging portion is exposed with which the engaging tool is engaged so that the press screw member can be rotated.

The movable portion 42 is angularly displaced about the axis line L2 of the second hinge portion 43. By so doing, the first press portion 85 is transferred along a circular arc-shaped transfer path about the axis line L2. The first press portion 85 is biased by the first spring member 91 in a tangent direction of the transfer path of the first press portion 85.

In the held state, the first press portion 85 abuts on the element main body 56 of the semiconductor laser element 2. In the held state, the proximal portion 98 of the first press portion 85 and the one end 97 in the axial direction of the first hole portion 94 are away from each other. Therefore, on the heat sink 5, the first press portion 85 elastically abuts on the element main body 56. The first press portion 85 can reliably push the element main body 56 onto the heat sink 5 by the spring force of the first spring member 91. The first press portion 85 pushes the element main body 56 in a direction which is vertical to the contact surface 72 of the heat sink 5. This makes it possible to reliably contact the radiating portion 58 of the semiconductor laser element 2 with the heat sink 5. Since the first press portion 85 elastically pushes the element main body 56, it is possible to reliably contact the radiating portion 58 with the heat sink while preventing a load given to the semiconductor laser element 2 from being too large. In addition, since the tip 95 of the first press portion 85 is formed to have a semispherical shape, the first press portion 85 can push the semiconductor laser element 2 without damaging the semiconductor laser element 2.

The second press portion 87 is elastically biased by the second elastic bias portion 88. The second elastic bias portion 88 comprises a second spring member 114, and a second spring support 115 for supporting the second spring member 114. The second spring member 114, the second spring support 115, and the second press portion 87 are provided on the movable portion 42. The second spring member 114 is composed of a coil spring. The movable portion 42 has a second hole portion 116 having a shape of a tube with a bottom. The second hole portion 116 is provided closer to the proximal portion of the movable portion 42 than the press screw member 93. The second hole portion 116 opens to the base portion 41 in the held state. By means of this second hole portion 116, the second spring support 115 is formed. In the second hole portion 116 is contained the second spring member 114 and a part of the second press portion 87. The second spring member 114 contacts the second spring support 115 and the second press portion 87 so that the second press portion 87 is biased by spring force to one side in the axial direction of the second press portion 87 in the held state. The second press portion 87 is composed of a pin member having a schematic right cylindrical shape.

A tip 117 of the second press portion 87 protrudes from the second holding surface 55 of the movable portion 42. The tip 117 of the second press portion 87 is formed into a flat surface. An inside diameter of the second hole portion 116, which is closer to the second holding surface 55, is formed to be smaller than an inside diameter of the other parts of the second hole portion 116. A proximal portion 118 of the second press portion 87 is formed to have a right cylindrical shape having a larger diameter than the inside diameter which is closer to the second holding surface 55 of the second hole portion 116. Thereby, in the developed state, the proximal portion 118 of the second press portion 87 abuts on a portion of the second hole portion 116, which is closer to the second holding surface 55, by spring force of the second spring member 114, so that the second press portion 87 is prevented from being detached from the movable portion 42. The second press portion 87 is formed of electrical isolating materials such as synthetic resin material.

The movable portion 42 is angularly displace about the axis line L2 of the second hinge portion 43. By so doing, the second press portion 87 is transferred along a circular arc-shaped transfer path about the axis line L2. The second press portion 87 is biased by the second spring member 114 in a tangent direction of the transfer path of the second press portion 87.

The movable portion 42 has a projecting portion 119 which protrudes from the second holding surface 55. The projecting portion 119 is respectively provided on both ends in the first direction A1 of the movable portion 42. The projecting portion 119 is inserted into the above-described positioning hole 59 of the frame 34. This makes it possible to position a plurality of the semiconductor laser elements 2 held by the holding portion 4.

In the held state, the second press portion 87 abuts on the element terminal portion 57 of the semiconductor laser element 2, and pushes the element terminal portion 57 onto the terminal piece 65 of the connecting terminal portion 63 provided on the base portion 41. In the held state, the proximal portion 118 of the second press portion 87 is away from the portion of the second hole portion 116, which is closer to the second holding surface 55 and with which the proximal portion 118 makes contact in the developed state. Thereby, on the first holding surface 54, the second press portion 87 elastically abuts on the element terminal portion 57. The second press portion 87 can reliably push the terminal of the element terminal portion 57 onto the terminal piece 65 by the spring force of the second spring member 114. The second press portion 87 pushes the element terminal portion 57 in a direction which is vertical to the first holding surface 54. This makes it possible to reliably contact the element terminal portion 57 with the terminal piece 65. In addition, an end face of the tip 117 of the second press portion 87 is formed in to a flat surface. Since each terminal of the element terminal portion 57 is composed of a thin metal wire, the end face of the tip 117 of the second press portion 87 is made to be flat so that the element terminal portion 57 can be reliably pushed by the second press portion 87 so as to contact the terminal piece 65.

The heat sink 5 and the movable portion 42 of the holding portion 4 are assembled in a heat insulated state. In other words, the heat sink 5 and the movable portion 42 are assembled with the base portion main body 62 formed of insulating materials therebetween so that the heat of the heat sink 5 is hardly transmitted to the movable portion 42.

In the held state, the radiating portion 58 of a plurality of the semiconductor laser elements 2 held by the holding portion 4 contact the heat sink 5. By so doing, it becomes easier to release the heat of a plurality of the semiconductor laser elements 2, which is generated by the driving thereof, into the housing space 13. In addition, it also becomes possible to make as equal as possible the temperature levels of a plurality of the semiconductor laser elements 2 contacting the same heat sink 5. In the other embodiments, materials for forming the heat sink 5 only need to have high heat conductivity. The heat sink 5 may be formed of copper and stainless steel, for instance.

The heat pipe 6 is connected to the heat sink 5 of the holding portion 4. Since the two holding portion 4 are away from each other having air interposed therebetween, the holding portion 4 are in the state where the heat is hardly transmitted to each other. The heat sink 5 is provided on the holding portion 4. The heat sinks 5 are away from each other. Since the heat sinks 5 are connected to each other via the heat pipe 6, the heat of the heat sink 5 is transmitted to the other heat sink 5 via the heat pipe 6. For instance, in a case where a first heat sink 5 provided on a first holding portion 4 has a higher temperature than that of a second heat sink 5 provided on a second holding portion 4, the heat pipe 6 transmits the heat from the first heat sink 5 to the second heat sink 5 as shown by an arrow C1 in FIG. 5. Moreover, for instance, in a case where the first heat sink 5 provided on the first holding portion 4 has a lower temperature than that of the second heat sink 5 provided on the second holding portion 4, the heat pipe 6 transmits the heat from the second heat sink 5 to the first heat sink 5 as shown by an arrow C2 in FIG. 5.

Thereby, even in a case where the holding portion 4 has the different number of the semiconductor laser elements 2, it is possible to reduce variation in temperature between the heat sink 5 on the holding portion 4 holding the large number of the operating semiconductor laser elements 2, and the heat sink 5 on the holding portion 4 holding the small number of the operating semiconductor laser elements 2, so that temperature variation of the semiconductor laser elements 2 held by the holding portion 4 can be as well reduced as possible.

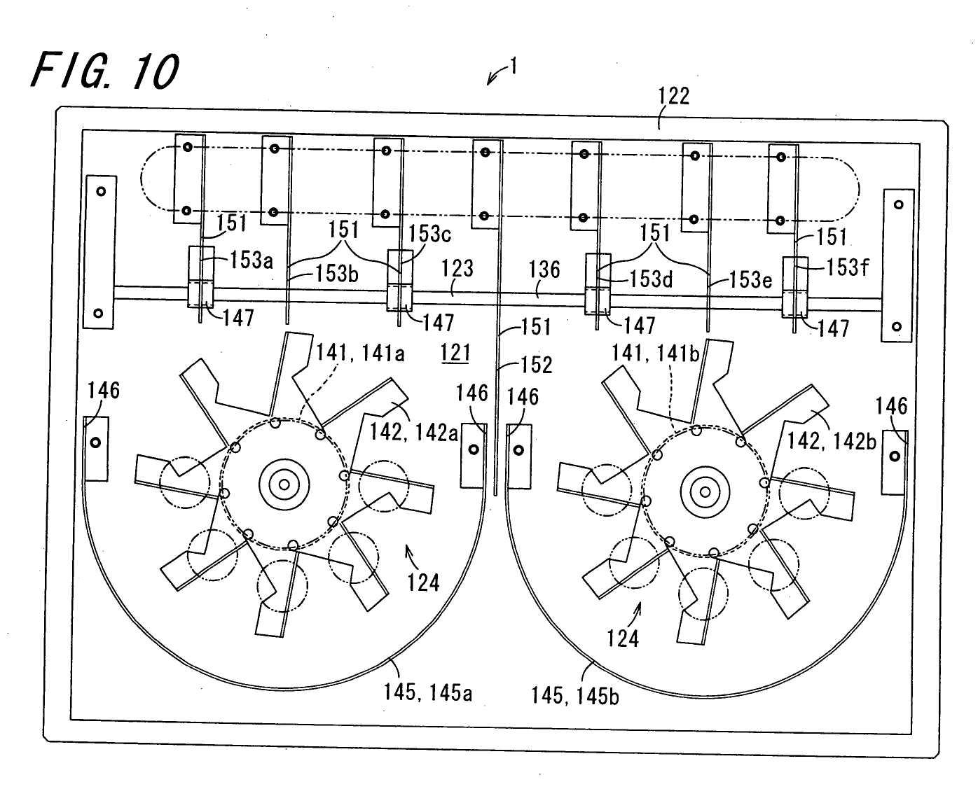

FIG. 10 is a sectional view showing the burn-in apparatus 1 taken on a section line X-X of FIG. 2. The thermostatic bath 3 is provided with the temperature adjusting portion 9. The temperature adjusting portion 9 comprises the temperature detecting portion 21, the temperature maintaining portion 22, and a temperature adjusting casing 122 for forming a predetermined temperature adjusting space 121. The temperature adjusting casing 122 comprises a heating portion 123, an air blowing portion 124, and a temperature control portion 125 for controlling the heating portion 123 and the air blowing portion 124.

The temperature detecting portion 21 comprises a thermocouple. The thermocouple is provided on a middle portion 126 of the heat pipe 6, which is exposed between the first heat sink 5a and the second heat sink 5b, so as to contact the heat pipe 6 at a position which is equidistant from the first heat sink 5a and the second heat sink 5b. The thermocouple contacts an outer surface of the case body 77 of the heat pipe 6.

The temperature adjusting casing 122 serving as a temperature adjusting space organizer is provided on an end in the third direction A3 of the thermostatic bath 3. The temperature adjusting casing 122 forms the predetermined temperature adjusting space 121. Hereinafter, the predetermined temperature adjusting space 121 may be simply referred to as a temperature adjusting space.

On a bottom wall portion 130 of the thermostatic main body 11, which faces the housing space 13, a first air hole 131 and a second air hole 132 are formed. The first air hole 131 is formed on an end 133 in the second direction A2 of the thermostatic bath main body 11. The first air hole 131 penetrates the thermostatic main body 11 in the third direction A3. The second air hole 132 is formed on the other end 134 in the second direction A2 of the thermostatic main body 11. The second air hole 132 penetrates the thermostatic main body 11 in the third direction A3. The first air hole 131 and the second air hole 132 are formed into an elongate hole shape extending between the both end 3a and end 3b in the first direction A1 of the thermostatic bath main body 11.

The first air hole 131 and the second air hole 132 are formed in the outside in the second direction A2 of the semiconductor laser elements 2 held by the holding portion 4. In other words, the first air hole 131 is formed in one second direction A2 of the first holding portion 4 while the second air hole 132 is formed in the other direction A2 of the second holding portion 4. The first air hole 131 and the second air hole 132 are communicated with the temperature adjusting space 121 of the temperature adjusting casing 122. The first air hole 131 and the second air hole 132 are formed to be substantially same and have plane symmetry with respect to one virtual plane which is vertical to the second direction A2. A dimension in the first direction A1 of the first air hole 131, and a dimension in the first direction A1 of the second air hole 132 are selected so as to be larger than an array width in the first direction A1 of a plurality of the semiconductor laser elements 2 held by the holding portion 4 and in addition, so as to be larger than the dimension in the longitudinal direction of the heat sink 5 and the holding portion 4. The first air hole 131 and the second air hole 132 are formed closer to the one end in the first direction A1 of the thermostatic bath main body 11 than a position where the semiconductor laser element 2 which is held at one end in the first direction A1 of the array of a plurality of the semiconductor laser elements 2 held by the holding portion 4. Moreover, the first air hole 131 and the second air hole 132 are formed closer to the other end in the first direction A1 of the thermostatic bath main body 11 than a position where the semiconductor laser element 2 which is held at the other end in the first direction A1 of the array of a plurality of the semiconductor laser elements 2 held by the holding portion 4. Inner peripheral surfaces of the thermostatic base main body 11, which define one side and the other side in the first direction A1 of the first air hole 131 and the second air hole 132, are formed into a curved surface which is convex outward. This makes it possible to prevent air passing through the first air hole 131 and the second air hole 132 from stagnating.

The temperature adjusting portion 9 supplies air into the predetermined housing space 13 of the thermostatic bath 3 via the first air hole 131, and discharges air in the housing space 13 inside the thermostatic bath 3 to the temperature adjusting space 121 via the second air hole 132. By so doing, the temperature adjusting portion 9 adjusts a temperature of the atmosphere in the housing space 13 so that the temperature falls within a predetermined temperature range.

The heating portion 123 is controlled by the temperature control portion 125 so as to heat atmosphere in the temperature adjusting space 121, that is to say, so as to heat air in the temperature adjusting space 121. The heating portion 123 comprises a nichrome wire heater 136. The heating portion 123 heats the atmosphere by generating heat. The temperature adjusting space 121 is selected to have the same volume capacity as that of the housing space 13. The nichrome wire heater 136 of the heating portion 123 is extends along the first direction A1, and disposed closer to the first air hole 131 in the second direction A2. The nichrome wire heater 136 is provided in the first direction A1 between both ends of the temperature adjusting casing 122. In a caser where a temperature of the atmosphere in the housing space 13 is being set within the predetermined temperature range, the heating portion 123 for heating the air is disposed in the housing space 13, for instance. In this case, the atmosphere closer to the heating portion 123 has a higher temperature while the atmosphere further way from the heating portion 123 has a lower temperature, so that the atmosphere in the housing space 13 may have a temperature variation which makes it difficult to maintain the temperature in the whole housing space 13 so as to fall within a predetermined temperature range. However, by supplying heated air from an external space of the thermostatic bath 3 to the housing space 13 via the first through hole 131, the temperature of the atmosphere in the whole housing space 13 can be increased in a state where the temperature variation of the atmosphere is as well reduced as possible and moreover, the temperature of the atmosphere in the housing space 13 can be easily maintained so as to fall within the predetermined temperature range.

The air blowing portion 124 supplies the air in the temperature adjusting space 121 to the housing space 13 via the first air hole 131 by blowing air. In addition, the air blowing portion 124 can discharge the air in the housing space 13 to the temperature adjusting space 121 by aspirating the air in the housing space 13 into the temperature adjusting space 121 via the second air hole 132.

With such a configuration, the air in the housing space 13 and the temperature adjusting space 121 can be circulated so that the temperature of the atmosphere of the housing space 13 can be adjusted. When the temperature control portion 125 determines that the temperature of the heat pipe 6 detected by the temperature detecting portion 21 becomes lower than a temperature within the predetermined temperature range, the temperature control portion 125 makes the heating portion 123 heat the atmosphere in the temperature adjusting space 121, and the air blowing portion 124 blow the air heated by the heating portion 123. By so doing, the heated air is supplied to the housing space 13 so as to increase the temperature in the housing space 13, with the result that the semiconductor laser element 2 on the testing is reduced from having a decreased temperature.

Further, when the temperature control portion 125 determines that the temperature of the heat pipe 6 detected by the temperature detecting portion 21 becomes higher than a temperature within the predetermined temperature range, the temperature control portion 22 makes the heating portion 123 stop heating the air in the temperature adjusting space 121, or the air blowing portion 124 stop blowing air and vacuuming up air, or alternatively both of the heating portion 123 and the temperature adjusting space 121 stop operations thereof. Thereby, the temperature in the housing space 13 is made to stop increasing so that excessive increase of the temperature of the semiconductor laser element 2 on the testing is reduced.

In the thermostatic bath 3, in the second direction A2, the air is supplied from the one end 133 to the housing space 13 while the air is discharge from the other end portion 134 to the housing space 13. Consequently, the air can be prevented as proficiently as possible from stagnating in the housing space 13, so that it is possible to reduce generation of the temperature variation in the housing space 13.

The air blowing portion 124 comprises a first rotation driving portion 141a, a second rotation driving portion 141b, a first impeller 142a, a second impeller 142b, and a flywheel 143. The first rotation driving portion 141a and the second rotation driving portion 141b will be collectively referred to as a rotation driving portion 141. The first impeller 142a and the second impeller 142b will be collectively referred to as an impeller 142.

The rotation driving portion 141 is composed of a motor, for instance. The impeller 142 is fixed to a rotary shaft 144 of the rotation driving portion 141. The impeller 142 rotates in a predetermined direction about a rotation axis line L3 of the rotary shaft 144 when the rotation driving portion 141 is driven. The rotary shaft 144 extends along the third direction A3. The impeller 142 can move the air in a direction away from the rotation axis line L3 by rotating about the rotation axis line L3. In other words, the impeller 142 can blow air. The flywheel 143 is respectively fixed to the rotary shaft 144 of the rotation driving portion 141. The flywheel 143 is not disposed in the temperature adjusting space 121, but disposed outside of the temperature adjusting casing 122. The flywheel 143 is provided between the impeller 142 and the rotation driving portion 141 for rotating the rotary shaft 144. By providing the flywheel 143, it is possible to prevent an acute change in rotation speed of the rotation driving portion 141 so that the impeller 142 stably blows air. The rotation axis line L3 of the rotary shaft 144 of the rotation driving portion 141 extends along the third direction A3. The impeller 142 is disposed in arrangement along the first direction A1. The impeller 142 and a part of the rotary shaft 144 are contained in the temperature adjusting space 121.

The impeller 142 is disposed closer to the second air hole 132 than the nichrome wire heater 136 in the second direction A2. This makes it possible to supply the air heated by the nichrome wire heater 136 to the housing space 13 via the first air hole 131 when the impeller 142 is rotated about the axis line of the rotary shaft 144.

The temperature adjusting casing 122 is provided with a first wind control plate 145a and a second wind control plate 145b. The first wind control plate 145a and the second wind control plate 145b are collectively referred to as a wind control plate 145 in a simple manner. The wind control plate 145 is provided so as to correspond to the impeller 142. The wind control plate 145 organizes air flow so that the air which moves by the rotation of the impeller 142 flows in a predetermined direction. The wind control plate 145 has an inner peripheral surface which is formed into a circular arc centered on the rotation axis line L3. The wind control plate 145 is composed of platy members, and formed outside in a radial direction having a center of the rotation axis line L3 of the impeller 142 so that the inner peripheral surface covers a substantial half circle of the impeller 142. The wind control plate 145 covers the impeller 142 from a side in the second direction A2, which side is opposite to a side having the first air hole 131 therein across the impeller 142 so that the air moves to the first air hole 131-side. In addition, the wind control plate 145 is provided that both ends 146 thereof cover the outside in the first direction A1 of the rotation axis line L3.

The nichrome wire heater 136 is provided, in the temperature adjusting space 121, on an opposite side to the wind control plate 145 with the impeller 142 therebetween. The nichrome wire heater 136 has a portion thereof extending in parallel with the first direction A1 between the both ends in the first direction A1 of the temperature adjusting casing 122. The nichrome wire heater 136 is fixed to the temperature adjusting casing 122 by a heater holding portion 147 while a predetermined gap is secured between the nichrome wire heater 136 and the temperature adjusting casing 122.

Moreover, the temperature adjusting casing 122 is provided with a first flow path forming portion 148 for guiding to the predetermined first air hole 131 the air which moves by the rotation of the impeller 142, and a second flow path forming portion 149 for guiding to the impeller 142 the air which is flowed from the second air hole 132. The first flow path forming portion 148 is formed, in the outside of the impeller 142, in a region which is closer to the thermostatic bath 3 than the impeller 42 and which is closer to the first air hole 131 than the rotation axis line L3.

Further, on one side in the second direction A2 of the impeller 142, the temperature adjusting casing 122 has a division plate 151 for diving in a direction in which the first air hole 131 extends, that is to say, in the first direction A1, the temperature adjusting space 121 into a plurality of predetermined spaces. The division plate 151 extends from the one end in the second direction A2 of the temperature adjusting casing 122 to a space which is closer in the second direction A2 to the impeller 142 than the nichrome wire heater 136. Thereby, the nichrome wire heater 136 is provided in a plurality of the predetermined spaces divided by the division plate 151, so that air in the predetermined spaces is heated.

The division plate 151 is a platy member. A thickness direction of the division plate 151 is parallel to the first direction A1. The division plate 151 is disposed on a center in the first direction A1 of the temperature adjusting casing 122. The division plate 151 has a center division plate 152 formed between the first wind control plate 145a and the second wind control plate 145b. The center division plate 152 is formed from the one end in the second direction A2 of the temperature adjusting casing 122 to the one end 146 of the wind control plate 145. By providing the center division plate 152, interference of the wind generated by the rotation of the impeller 142 is prevented. Further, in the first direction A1, the division plate 151 comprises a plurality of adjusting division plates 153 disposed between the center division plate 152 and an inner peripheral surface of the temperature adjusting casing 122, which faces the temperature adjusting space 121. The adjusting division plate 153 comprises a first adjusting division plate 153a, a second adjusting division plate 153b, a third adjusting division plate 153c, a fourth adjusting division plate 153d, a fifth adjusting division plate 153e, and a sixth adjusting division plate 153f.

The first adjusting division plate 153a, the second adjusting division plate 153b, and the third adjusting division plate 153c are provided on one side in the first direction A1 of the center division plate 152. The fourth adjusting division plate 153d, the fifth adjusting division plate 153e, and the sixth adjusting division plate 153f are provided on the other side in the first direction A1 of the center division plate 152. The air which moves by the rotation of the impeller 142 flows into the predetermined spaces divided by the division plate 151.

Distances in the first direction A1 among the first adjusting division plate 153a, the second adjusting division plate 153b, the third adjusting division plate 153c, the fourth adjusting division plate 153d, the fifth adjusting division plate 153e, and the sixth adjusting division plate 153f are selected so that the temperature of the air flowed from the first air hole 131 becomes substantially uniform when the air in all the spaces sectioned by the first adjusting division plates 153a, the second adjusting division plate 153b, the third adjusting division plate 153c, the fourth adjusting division plate 153d, the fifth adjusting division plate 153e, and the sixth adjusting division plate 153f is heated by the nichrome wire heater 136 and then, the air heated in all the spaces is supplied to a first processing space by the air blowing portion 124. This makes it possible to further enhance temperature uniformity, in a direction in which the first air hole 131 extends, that is to say, in the first direction A1, of the heater air supplied from the first air hole 131 to the housing space 13. In the embodiment, there are provided six division plates of the first adjusting division plates 153a, the second adjusting division plate 153b, the third adjusting division plate 153c, the fourth adjusting division plate 153d, the fifth adjusting division plate 153e, and the sixth adjusting division plate 153f, but the number of the division plates is not limited to six in the other embodiments of the invention.

In addition, the temperature adjusting casing 122 is provided with the first flow path forming portion 148 for guiding to the first air hole 131 the air which moves by the rotation of the impeller 142, and the second flow path forming portion 149 for guiding to the impeller 142 the air which is flowed from the second air hole 132. The first flow path forming portion 148 is formed so as to communicate the predetermined space formed by the division plates 151 with the first air hole 131. By the rotation of the impeller 142, the air in the temperature adjusting space 121 moves to the one side in the second direction A1 as shown by an arrow E1 in FIG. 3. The air transferred to the one side in the second direction A2 passes through the predetermined spaces sectioned by the division plate 151, and then is transferred from the end in the second direction A2 of the temperature adjusting casing 122 to the other side in the third direction A3 as shown by an arrow E2 in FIG. 3. Subsequently, the air passes through the first flow path forming portion 148 and then the first air hole 131 so as to flow into the housing space 13. The air flowed into the housing space 13 is directed to the other side in the second direction A2 as shown by an arrow E3 in FIG. 3. In the housing space 13, the air transferred to the other side in the second direction A2 passes through the second air hole 132, and flows from the end in the second direction A2 of the thermostatic bath 3 into the one side in the third direction A3 as shown by an arrow E4 in FIG. 3. By the aspiration power due to the rotation of the impeller 142, the air flows into the temperature adjusting space 121. The air flowed into the temperature adjusting space 121 is guided to a vicinity of the rotation axis line L3 of the impeller 142 by the second flow path forming portion 149. The second flow path forming portion 149 is formed between the vicinity of the rotation axis line L3 of the impeller 142, and the second air hole 132, in a region which is closer to the thermostatic bath 3 than the impeller 42 and which is closer to the second air hole 132. Due to such rotation of the impeller 142, the air in the housing space 13 and the temperature adjusting space 121 can be circulated.

The temperature adjusting casing 122 is provided with a protective member 155 for protecting the rotation driving portion 141 which protrudes to one side in the third direction A3 of the temperature adjusting casing 122. The protective member 155 protrudes to the one side in the third direction A3 of the temperature adjusting casing 122, and covers the rotation driving portion 141 from outside around the rotation axis line L2.

In the housing space 13, the air flows from the first air hole 131 to the second air flow 132. Since the first heat sink 5 provided on the first holding portion 4 which is closer to the first air hole 131, easily receives wind compared to the second heat sink 5 provided on the second holding portion 4, the temperature of the first heat sink 5 decreases more easily than the temperature of the second heat sink 5. However, even when the temperature of the first heat sink 5 decreases, generation of the temperature difference between the first heat sink 5 and the second heat sink 5 due to the transfer of the heat can be as well constrained as possible by the heat pipe 6. Moreover, check condition for a plurality of the semiconductor laser elements 2 can be made as uniform as possible, so that reliability of the testing can be enhanced. Further, the holding portion 4 can be disposed regardless of a moving direction of the air in the housing space 13, so that freedom degree of the design can be enhanced.

Table 1 shown a result of the experiment about the temperature of the semiconductor laser elements 2 at the time when a plurality of the semiconductor laser elements 2 are driven as being held by the holding portion 4 of the burn-in apparatus 1 in the embodiment. In Table 1, the first holding portion 4 is indicated by “A” while the second holding portion 4 is indicated by “B”. In each experiment of experiment numbers 1 to 11 shown in Table 1, the heat pipe 6 having a diameter of 4 mm is employed. In each experiment of experiment numbers 12 and 13 shown in Table 1, the heat pipe 6 having a diameter of 6 mm is employed. A 50 mm range of the heat pipe 6, which extends from one end to the other end in an extending direction thereof, is made to be a heating portion while a 250 mm range of the heat pipe 6, which extends from the other end to the one end in the extending direction thereof, is made to be a cooling portion. In this case, a heat transfer resistance of the heat pipe 6 having a diameter of 4 mm is 0.38 K/W while a heat transfer resistance of the heat pipe 6 having a diameter of 6 mm is 0.24 K/W.

TABLE 1

| | Lighting Condition | | | Temp. of A [° C.] | | | | | Temp. of B [° C.] | | | | |
|---|---|---|---|---|---|---|---|---|---|---|---|---|---|
| No. | Total | A | B | F-CH1 | F-CH5 | F-CH10 | F-CH15 | F-CH20 | R-CH1 | R-CH5 | R-CH10 | R-CH15 | R-CH20 |
| 1 | 38 Lightings | 19 | 19 | 69.2 | 71.4 | 72.1 | 71.1 | 72.0 | 70.9 | 67.3 | 72.5 | 68.6 | 71.6 |
| 2 | 38 Lightings | 19 | 19 | 69.6 | 71.7 | 72.5 | 71.3 | 71.6 | 70.8 | 67.4 | 72.5 | 68.6 | 71.6 |
| 3 | 38 Lightings | 19 | 19 | 69.4 | 72.0 | 72.2 | 70.7 | 70.8 | 71.0 | 67.2 | 72.2 | 68.6 | 71.6 |
| | Average of | 19 | 19 | 69.4 | 71.7 | 72.3 | 71.0 | 71.5 | 70.9 | 67.3 | 72.4 | 68.6 | 71.6 |
| | No. 1-3 | | | | | | | | | | | | |
| 4 | 29 Lightings | 19 | 10 | 68.5 | 70.3 | 70.4 | 69.5 | 69.5 | 68.4 | 66.2 | 69.6 | 66.5 | 69.7 |
| 5 | 24 Lightings | 19 | 5 | 68.6 | 70.5 | 70.4 | 69.5 | 68.5 | 67.2 | 65.4 | 68.2 | 66.2 | 68.2 |
| 6 | 20 Lightings | 19 | 1 | 68.0 | 69.3 | 69.3 | 68.5 | 67.5 | Off | Off | 67.3 | Off | Off |
| | | | | | | | | | 63.8 | 62.7 | | 63.9 | 64.4 |
| 7 | 19 Lightings | 19 | 0 | 67.8 | 69.3 | 68.9 | 68.4 | 67.2 | Off | Off | Off | Off | Off |
| | | | | | | | | | 61.0 | 61.0 | 61.0 | 61.0 | 61.0 |
| 8 | 10 Lightings | 10 | 0 | 65.4 | 65.8 | 66.0 | 65.7 | 65.7 | Off | Off | Off | Off | Off |
| | | | | | | | | | 61.0 | 61.0 | 61.0 | 61.0 | 61.0 |
| 9 | 5 Lightings | 5 | 0 | 64.0 | 64.2 | 64.4 | 64.1 | 64.0 | Off | Off | Off | Off | Off |
| | | | | | | | | | 61.0 | 61.0 | 61.0 | 61.0 | 61.0 |
| 10 | 1 Lightings | 1 | 0 | Off | Off | 63.6 | Off | Off | Off | Off | Off | Off | Off |
| | | | | 61.1 | 60.8 | | 61.0 | 61.0 | 61.0 | 61.0 | 61.0 | 61.0 | 61.0 |
| 11 | 20 Lightings | 10 | 10 | 67.2 | 67.9 | 68.4 | 68.0 | 67.7 | 67.4 | 66.6 | 68.2 | 66.5 | 68.6 |
| 12 | 38 Lightings | 19 | 19 | 67.5 | 69.5 | 70.4 | 71.1 | 67.7 | 67.4 | 67.7 | 69.2 | 69.4 | 67.3 |
| 13 | 20 Lightings | 10 | 10 | 65.8 | 66.8 | 67.4 | 67.4 | 67.1 | 66.2 | 66.8 | 66.7 | 66.8 | 66.6 |

| | Temp. | Temp. | Total Temp. | Average | Average | Total | Comparison |
|---|---|---|---|---|---|---|---|
| | Distribution | Distribution | Distribution | Tem. | Tem. | Average | With |
| No. | of A [° C.] | Of B [° C.] | [° C.] | of A [° C.] | of B [° C.] | Tem. [° C.] | Standard |
| 1 | 2.9 | 5.2 | 5.2° C./10 lights | 71.2 | 70.2 | 70.7° C./10 lights | |
| 2 | 2.9 | 5.1 | 5.1° C./10 lights | 71.3 | 70.2 | 70.7° C./10 lights | |
| 3 | 2.8 | 5.0 | 5.0° C./10 lights | 71.0 | 70.1 | 70.5° C./10 lights | |
| | 2.9 | 5.1 | 5.1° C./10 lights | 71.2 | 70.2 | 70.6° C./10 lights | Standard (ø 4) |
| 4 | 1.9 | 3.4 | 4.2° C./10 lights | 69.6 | 68.1 | 68.8° C./10 lights | 1.8° C. from standard |
| 5 | 2.0 | 2.8 | 4.3° C./10 lights | 69.5 | 67.0 | 68.3° C./10 lights | 2.3° C. from standard |
| 6 | 1.8 | | 2.3° C./6 lights | 68.5 | 67.3 | 67.7° C./6 lights | 2.9° C. from standard |
| 7 | 2.1 | | 2.1° C./5 lights | 68.3 | | 68.3° C./5 lights | 2.3° C. from standard |
| 8 | 0.6 | | 0.6° C./5 lights | 65.7 | | 65.7° C./5 lights | 5.0° C. from standard |
| 9 | 0.4 | | 0.4° C./5 lights | 64.1 | | 64.1° C./5 lights | 6.6° C. from standard |
| 10 | | | | 63.6 | | 63.6° C./1 lights | 7.1° C. from standard |
| 11 | 1.2 | 2.6 | 2.4° C./10 lights | 67.8 | 67.5 | 67.6° C./10 lights | 3.1° C. from standard |
| 12 | 3.6 | 2.1 | 3.8° C./10 lights | 69.2 | 68.2 | 68.7° C./10 lights | Standard (ø 6) |
| 13 | 1.6 | 0.6 | 1.6° C./10 lights | 66.9 | 66.6 | 67.0° C./10 lights | 1.7° C. from standard |

In the experiments, the first holding portion 4a and the second holding portion 4b were made to hold 20 semiconductor laser elements 2, respectively. Further, in the experiments, among the semiconductor laser elements 2 held by the holding portion 4, the temperatures of first, fifth, tenth, fifteenth, and twentieth semiconductor laser elements 2 held in the order from one side to the other side in the first direction A1 were detected. Among the semiconductor laser elements 2 held by the first holding portion 4, the first semiconductor laser element 2 is indicated by F-CH1, the fifth semiconductor laser element 2 is indicated by F-CH5, the tenth semiconductor laser element 2 is indicated by F-CH10, the fifteenth semiconductor laser element 2 is indicated by F-CH15, and the twentieth semiconductor laser elements 2 is indicated by F-CH20, which are held in the order from the one side to the other side in the first direction A1. Further, among the semiconductor laser elements 2 held by the second holding portion 4, the first semiconductor laser element 2 is indicated by R-CH1, the fifth semiconductor laser element 2 is indicated by R-CH5, the tenth semiconductor laser element 2 is indicated by R-CH10, the fifteenth semiconductor laser element 2 is indicated by R-CH15, and the twentieth semiconductor laser elements 2 is indicated by R-CH20, which are held in the order from the one side to the other side in the first direction A1.

The Table 1 shows a test number, a lighting condition, a temperature of A, a temperature of B, a temperature distribution of A, a temperature distribution of B, a total temperature distribution, an average temperature of A, an average temperature of B, a total average temperature, and comparison with standard.

The lighting condition shows the number of the lighted semiconductor laser elements 2. The lighting condition shows the number of the total lightings, the number of the semiconductor laser elements 2 held by the first holding portion 4a (A), and the number of the semiconductor laser elements 2 held by the second holding portion 4b (B). For instance, in the case of the experiment number 4, the Table 1 shows that 29 semiconductor laser elements 2 were lighted as a whole, and among the semiconductor laser elements 2 held by the first holding portion 4, 19 semiconductor laser elements 2 were lighted, and among the semiconductor laser elements 2 held by the second holing portion 4, 10 semiconductor laser elements 2 were lighted.

The temperature of A shows temperatures indicated by the above-described F-CH1, F-CH5, F-CH10, F-CH15, and F-CH 20. Among the semiconductor laser elements 2 indicated by the F-CH1, F-CH5, F-CH10, F-CH15, and F-CH 20, semiconductor laser elements 2 which were blacked out, are denoted by “Off”.

The temperature of B shows temperatures indicated by the above-described R-CH1, R-CH5, R-CH10, R-CH15, and R-CH 20. Among the semiconductor laser elements 2 indicated by the R-CH1, R-CH5, R-CH10, R-CH15, and R-CH 20, semiconductor laser elements 2 which were blacked out, are denoted by “Off”.

The temperature distribution of A shows a difference between the maximum temperature and the minimum temperature of the lighted semiconductor laser elements 2 indicated by the F-CH1, F-CH5, F-CH10, F-CH15, and F-CH 20. In other words, the temperature distribution of A shows a temperature variation of the semiconductor laser elements 2 held by the first holding portion 4a.

The temperature distribution of B shows a difference between the maximum temperature and the minimum temperature of the lighted semiconductor laser elements 2 indicated by the R-CH1, R-CH5, R-CH10, R-CH15, and R-CH 20. In other words, the temperature distribution of B shows a temperature variation of the semiconductor laser elements 2 held by the second holding portion 4b.

The total temperature distribution shows a difference between the maximum temperature and the minimum temperature of the lighted semiconductor laser elements 2 indicated by the F-CH1, F-CH5, F-CH10, F-CH15, F-CH 20, R-CH1, R-CH5, R-CH10, R-CH15, and R-CH 20. In other words, the total temperature distribution shows a temperature variation of the semiconductor laser elements 2 held by the first holding portion 4a and second holding portion 4b.

The average temperature of A shows an average temperature of the lighted semiconductor laser elements 2 indicated by the F-CH1, F-CH5, F-CH10, F-CH15, and F-CH 20.

The average temperature of B shows an average temperature of the lighted semiconductor laser elements 2 indicated by the R-CH1, R-CH5, R-CH10, R-CH15, and R-CH 20.

The total average temperature shows an average temperature of the lighted semiconductor laser elements 2 indicated by the F-CH1, F-CH5, F-CH10, F-CH15, F-CH 20, R-CH1, R-CH5, R-CH10, R-CH15, and R-CH 20.

In the cases of the experiment numbers 1 to 3, among the semiconductor laser elements 2 held by the first holding portion 4 and second holding portion 4, 19 semiconductor laser elements 2 were lighted. The Table 1 shows average values for all items of the experiment numbers 1 to 3. When the average values of the experiment numbers 1 to 3 are focused on, it is found that the temperature variation of the semiconductor laser elements 2 held by the first holding portion 4a is 2.9° C., and the temperature variation of the semiconductor laser elements 2 held by the second holding portion 4b is 5.1° C. Moreover, the temperature variation of the whole semiconductor laser elements 2 is 5.1° C. This indicates that, when the holding portion 4 is viewed individually, the semiconductor laser elements 2 held by the holding portion 4 have a small temperature variation and in addition, when all holding portion 4 are viewed, the semiconductor laser elements 2 have also a small temperature variation.

The comparison with standard shows a difference between the total average temperature and the total average temperature serving as standard, of the semiconductor laser elements in the experiment of the experiment number. The smaller this difference is, the more same testing conditions the semiconductor laser elements 2 have regardless of the number of the lighted semiconductor laser elements 2 held by the holding portion 4. In other words, among a plurality of the semiconductor laser elements 2 held by the holding portion 4, the temperatures of the semiconductor laser elements 2 can be as close as possible, for instance, between the case where 19 semiconductor laser elements 2 are lighted and the case where only 10 semiconductor laser elements 2 are lighted. This makes it possible, in the testing of a plurality of the semiconductor laser elements 2 by means of the burn-in apparatus 1, to make the testing conditions as same as possible for not only a plurality of the semiconductor laser elements 2 contained in the housing space of the thermostatic bath 3 at one testing, but also all the semiconductor laser elements 2 which are tested by means of the burn-in apparatus 1. Highly reliable test results can be obtained when the temperature of the semiconductor laser elements 2 is within a range of 5° C. more or less than the standard temperature, preferably 3° C. more or less than the standard temperature, in the comparison with standard.

In a case where a plurality of the semiconductor laser elements 2 include the semiconductor laser element 2 which causes operational failure, the temperature of the semiconductor laser element 2 decreases lower than the semiconductor laser element 2 which normally operates. Moreover, a portion of the heat sink 5, which contacts the semiconductor laser element 2 causing operational failure, has a lower temperature than the temperature of a portion of the heat sink 5, which abuts on the semiconductor laser element 2 normally operating. This leads decrease of the temperature of the semiconductor laser elements 2 around the semiconductor laser element 2 which cases operational failure. However, in the burn-in apparatus 1, the heat pipe 6 having higher heat conductivity than that of the heat sink 5 transfers the heat of the heat sink 5. Thereby, the temperature variation of the semiconductor laser elements 2 can be as well reduced as possible so that the semiconductor laser element 2 can have as uniform a temperature as possible. Such equalization of the temperature of the semiconductor laser element 2 enables equalization of the testing condition of the semiconductor laser elements 2, so that the reliability of the burn-in test and aging test can be enhanced.

Further, in the burn-in apparatus 1, even when it is necessary to change the temperature in mid-course of the burn-in test and aging test, the heat pipe 6 transfers the heat of the heat sink 5 so that the temperature of the semiconductor laser element 2 can be swiftly made to follow a command for changing the temperature.

In the burn-in apparatus 1, the semiconductor laser elements 2 are contained in a plurality of the housing spaces 13 of the thermostatic bath 3, and the atmosphere in the housing space 13 is maintained within a predetermined temperature range. In this state, the operational state detecting portion 8 outputs a predetermined signal for indicating a state of the to-be-driven semiconductor laser element 2. By obtaining the predetermined signal, the initial failure of the semiconductor laser element 2 can be detected and moreover, it is possible to learn the operational state of the semiconductor laser element 2 under the predetermined testing conditions.

Further, it becomes easy to dispose the semiconductor laser element 2 and the light receiving element 26 inside the housing space 13 when the housing space 13 is exposed to the external space of the thermostatic bath 3 by relatively moving the thermostatic bath main body 11 and the thermostatic bath lid 12. For instance, when the light receiving element 26 has troubles, it is possible to detach the light receiving element 26, so that exchange and repair thereof become easy. In addition, since it becomes easy to exchange the semiconductor laser element 2, the efficiency of the testing is enhanced.

Moreover, in the burn-in apparatus 1, the atmosphere in the housing space 13 containing the predetermined semiconductor laser element 2 is not heated directly by the nichrome wire heater 136, but the atmosphere in the temperature adjusting space 121 is first heated and then, this heated atmosphere is transferred into the housing space 13 by the air blowing portion 124. Such configuration prevents only a part of the atmosphere in the housing space 13 from having an increased temperature, so that the temperature of the atmosphere in the housing space 13 can be maintained to be substantially uniform within the predetermined temperature range.

The burn-in apparatus 1 of the embodiment has two holding portions 4. However, in the other embodiments of the invention, the burn-in apparatus 1 may be configured to have three or more holding portions 4. In this case, it is possible to obtain the same effect as that of the burn-in apparatus 1 in the above-described embodiment by connecting the heat sink 5 provided on the holding portion 4 with the heat pipe 6.

The burn-in apparatus 1 of the embodiment is used for the burn-in test and aging test of the semiconductor laser element 2, but may also be used for the burn-in test and aging test of, for instance, a light emitting diode (abbreviated as LED) and an integrated circuit (abbreviated as IC) chip without being limited to the semiconductor laser element 2.

Further, in the embodiment, the holding portion 4 holds the semiconductor laser elements 2 in a row in the first direction A1, but the holding portion 4 is not limited to holding the semiconductor laser elements 2 in this arrangement. In the other embodiments of the invention, the holding portion 4 may hold the semiconductor laser elements 2 in a given array.

Further, in the other embodiments of the invention, the aging test of the semiconductor laser element 2 can be conducted in the environment having a predetermined temperature by evaluating changes in light outputs in a case where the driving current of the semiconductor laser element 2 is maintained to be constant. Such a test is referred to as an ACC (automatic current control) test. In this case, the driving portion 23 makes the driving current of the semiconductor laser element 2 constant, and gives the output portion 25 the information corresponding to the light intensity detected by the light receiving portion 24.

In the above-described embodiment, the predetermined gas is set as air, but incombustible gas other than air can also be used for the predetermined gas. For instance, a nitrogen gas may be used.

In the burn-in apparatus 1 of the embodiment, the heat sink 5 is formed of aluminum material. However, in the other embodiments of the invention, the heat sink 5 may be formed of copper material and stainless steel material. When the heat sink 5 is formed of copper material, the temperature variation of the semiconductor laser elements 2 can be more equalized.

In the other embodiments of the invention, the case body 77 of the heat pipe 6 and the heat sink 5 may be formed in a single body.

In the burn-in apparatus 1, the silicone grease containing the metal powder is interposed between the heat sink 5 and the heat pipe 6. However, in the other embodiments of the invention, the heat sink 5 and the heat pipe 6 may be made to directly contact each other. Even with such configuration, the same effect can be obtained.

In the other embodiments of the invention, the heat pipe 6 connected to the first heat sink 5a and second heat sink 5b may be formed into a circular ring. In other words, the both ends of the heat pipe 6 in FIG. 1 may be formed to be connected to each other. By so doing, the heat is more smoothly transferred between the first heat sink 5a and the second heat sink 5b so that the temperature variation of the semiconductor laser element 2 held by the holding portion 4 can be further reduced. In the burn-in apparatus of each of the embodiments, it is possible to obtain the same effect as that of the burn-in apparatus 1 of the above-described embodiment.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A burn-in apparatus comprising:
a thermostatic bath having a housing space capable of housing a plurality of test objects having a heat generating portion which generates heat in operation thereof;
a holding portion provided in the housing space, for holding a plurality of test objects;
operational state detecting portion for giving test objects held by the holding portion an operational signal for operating the test objects, detecting outputs of the test objects to which the operation signal is given, and then outputting a detected result as a operational state;
a heat sink provided in the housing space, for contacting the heat generating portions of the test objects held by the holding portion; and
a heat pipe provided on the heat sink along an array direction of the test objects held by the holding portion, for transmitting heat of the heat sink.

2. The burn-in apparatus of claim 1, wherein a plurality of the holding portions are provided so as to be away from each other, and a plurality of the heat sinks are provided so as to correspond to the holding portions, the heat sinks being connected to each other via the heat pipe.

3. The burn-in apparatus of claim 1, wherein the heat pipe is connected to the heat sink via a paste-like filling material composed of metal powder and grease.

4. The burn-in apparatus of claim 1, wherein the holding portion has a press portion for elastically pushing onto the heat sink a radiating portion of the test object, for radiating the heat generated by the heat generating portion.

5. The burn-in apparatus of claim 1, further comprising:
a temperature detecting portion for detecting a temperature of the heat pipe; and
a temperature maintaining portion for maintaining, based on a detected result of the temperature detecting portion, a temperature of atmosphere in the housing space so that a plurality of the test objects held by the holding portion have temperatures within a predetermined temperature range.
